(19) United States
(12) Patent Application Publication
(10) Pub. No.: US 2026/0220949 A1
(43) Pub. Date: Jul. 30, 2026

(54) METHOD OF DETERMINING SPATIAL DIFFERENCES BETWEEN THREE-DIMENSIONAL OBJECTS

(71) Applicant: CUPIX, INC., Gyeonggi-do (KR)

(72) Inventors: SeockHoon BAE, Seoul (KR); Jun Young PARK, Gyeonggi-do (KR); Yoon Sung JI, Seoul (KR)

(73) Assignee: CUPIX, INC., Gyeonggi-do (KR)

(21) Appl. No.: 19/574,459

(22) Filed: Mar. 23, 2026

Related U.S. Application Data
(63) Continuation of application No. PCT/KR2024/014298, filed on Sep. 23, 2024.

(30) Foreign Application Priority Data
Sep. 14, 2024 (KR) 10-2024-0126268

(51) Int. Cl. G06V 20/64; G06V 10/764

(52) U.S. Cl. CPC G06V 20/653; G06V 10/764

(57) ABSTRACT

The present disclosure relates to a method of determining spatial differences between three-dimensional objects, and more particularly, to a method of determining spatial differences between three-dimensional objects to identify differences between a design and a construction by comparing design data for three-dimensional objects constituting a structure arranged in a three-dimensional space with scan data for an actually fabricated or constructed three-dimensional object. The method of determining spatial differences between three-dimensional objects, according to the present disclosure, has the effect of accurately and efficiently identifying spatial differences of individual objects by effectively comparing design data of a three-dimensional structure with scan data for an actually constructed site.

### CROSS-REFERENCE TO RELATED APPLICATION

This application is a continuation of and claims the priority benefit of PCT application serial no. PCT/KR2024/014298, filed on September 23, 2024, which claims the priority benefit of Korea Patent Application No. 10-2024-0126268 filed on September 14, 2024. The entirety of each of the above mentioned patent applications is hereby incorporated by reference herein and made a part of this specification.

### BACKGROUND

### TECHNICAL FIELD

The present disclosure relates to a method of determining spatial differences between three-dimensional objects, and more particularly, to a method of determining spatial differences between three-dimensional objects to identify differences between a design and a construction by comparing design data for three-dimensional objects constituting a structure arranged in a three-dimensional space with scan data for an actually fabricated or constructed three-dimensional object.

### Related Art

There is a demand in various technical fields for identifying changes in the shape or color of a specific space over time.

For example, the construction industry necessitates such tasks in various manners to monitor the progress of construction work. There is a need to frequently determine whether a construction project is proceeding according to the design and the extent to which actual construction has progressed based on the design.

Identifying the progress of construction serves as a management metric for construction projects and is an essential, frequently occurring procedure for invoicing and settling subcontractor payments, as well as for verifying construction results. In the related art, such tasks are handled by a person visiting the construction site to visually compare it with design drawings and perform actual measurements or surveys. Performing these tasks manually requires a significant amount of time and effort and involves high costs. Accordingly, automating the identification of construction progress by comparing design drawings with the actual construction status allows for a substantial reduction in time, labor, and expenses.

Recently, as the design, construction, and management of buildings are all centered on three-dimensional building information models (BIMs), productivity and efficiency have been significantly improved. Consequently, the proportion of new construction projects incorporating three-dimensional BIMs starting from the design phase is gradually increasing. In addition, BIMs are utilized as basic building representation databases in systems for enhancing city operation efficiency based on digital models of an entire city, such as a smart city.

In this regard, there has been a need for a method of scanning the shape of an actually constructed or fabricated three-dimensional structure to effectively identify a difference from a design shape based on three-dimensional design data obtained via a BIM. That is, there is a need for a method of photographing an actual structure to obtain scan data and comparing the scan data with design data (BIM) to effectively identify whether any discrepancies exist in the shape, position, and orientation of individual constituent objects relative to the design.

### SUMMARY

The present disclosure has been devised to satisfy the above-described needs, and an objective of the present disclosure is to provide a method of determining spatial differences between three-dimensional objects, capable of accurately and rapidly identifying differences between individual constituent objects by comparing design data obtained via a building information model (BIM) with scan data of an actual site constructed in accordance with the design data.

A method of determining spatial differences between three-dimensional objects by comparing design data of a three-dimensional structure with scan data for the structure to identify a spatial difference between the design data and the scan data includes: (a) receiving and storing, by a design data receiving module, the design data partitioned into constituent objects that constitute the structure; (b) receiving the scan data obtained by scanning the structure and storing the same in the form of point cloud data, by a scan data receiving module; (c) globally aligning, by an alignment module, the scan data with respect to the design data; (d) classifying, by an assignment module, points of the scan data in the form of the point cloud data to correspond to the respective constituent objects of the design data, based on spatial proximity; and (e) performing, by a comparison module, an iterative closest point (ICP) algorithm on at least some of the constituent objects of the design data and the points of the scan data classified as corresponding to the constituent objects, to generate differences in position and orientation between the constituent objects and the points of the scan data, which correspond to each other, as error information.

A method of determining spatial differences between three-dimensional objects, according to the present disclosure, has the effect of accurately and efficiently identifying spatial differences of individual objects by effectively comparing design data of a three-dimensional structure with scan data for an actually constructed site.

### BRIEF DESCRIPTION OF THE DRAWINGS

FIG. 1 is a block diagram of an apparatus for performing an example of a method of determining spatial differences between three-dimensional objects, according to the present disclosure.

FIG. 2 is a flowchart for performing an example of a method of determining spatial differences between three-dimensional objects, according to the present disclosure.

FIGS. 3 and 4 are diagrams for describing a process of determining spatial differences between three-dimensional objects, according to the present disclosure.

### DETAILED DESCRIPTION

Hereinafter, a method of determining spatial differences between three-dimensional objects, according to an embodiment of the present disclosure, will be described with reference to the accompanying drawings.

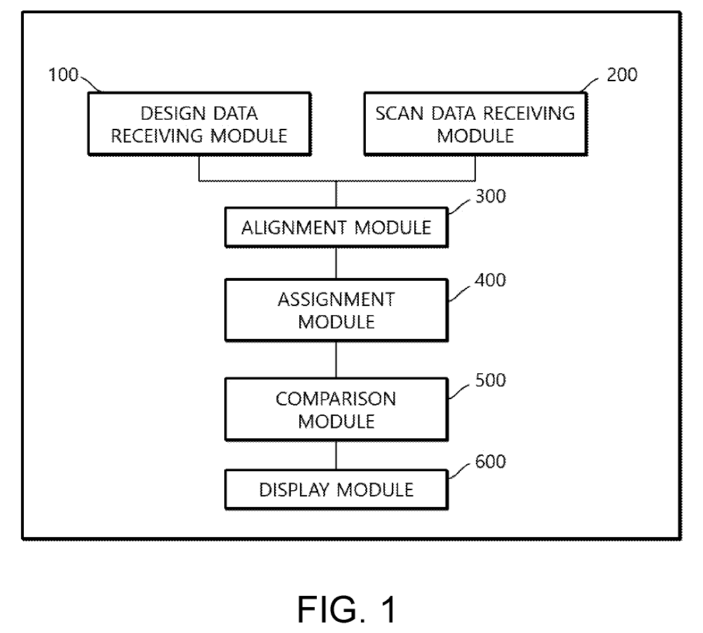

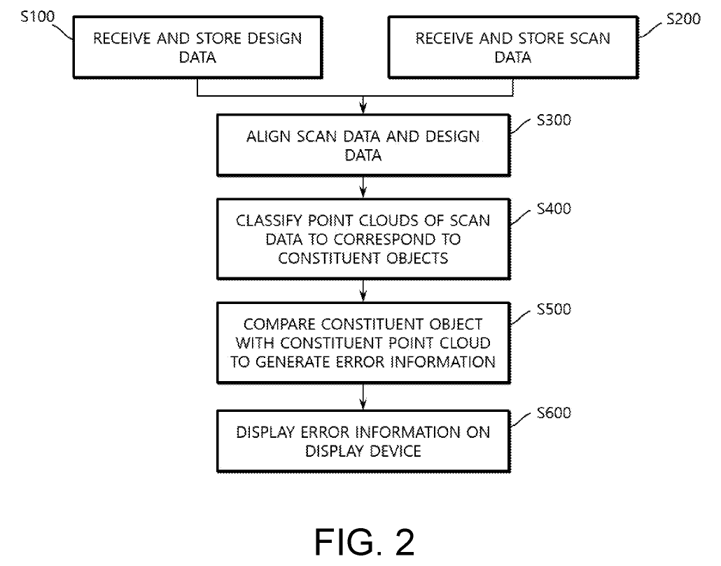

FIG. 1 is a block diagram of an apparatus for performing an example of a method of determining spatial differences between three-dimensional objects, according to the present disclosure, and FIG. 2 is a flowchart for performing an example of a method of determining spatial differences between three-dimensional objects, according to the present disclosure.

Referring to FIG. 1, an apparatus for performing a method of determining spatial differences between three-dimensional objects, according to the present disclosure, includes a design data receiving module 100, a scan data receiving module 200, an alignment module 300, an assignment module 400, a comparison module 500, and a display module 600.

The design data receiving module 100 receives and stores design data partitioned into constituent objects constituting a structure. That is, the design data corresponds to building information model (BIM) data of a structure corresponding to a building or a construction. The design data receiving module 100 receives and stores design data including geometric and spatial information about individual constituent objects constituting a structure. The individual constituent objects included in the design data include three-dimensional objects such as walls, floors, ceilings, and columns of a building. The design data includes information about the shape, position, orientation, and the like of the individual constituent objects.

The scan data receiving module 200 receives scan data obtained by scanning a structure that is actually fabricated or under fabrication based on the design data, and stores the received scan data in the form of point cloud data. The scan data may be data obtained through laser scanning or may be a set of two-dimensional photographic images captured by using a 360-degree camera or the like. The scan data receiving module 200 may receive the two-dimensional photographic images along with intrinsic camera parameters of the camera that has captured them, arrange the two-dimensional photographic images in a three-dimensional space, and convert and store the captured space into point cloud data by recognizing common features among the photographic images, or may receive and store, as scan data, only point cloud data generated by a separate apparatus performing such processing.

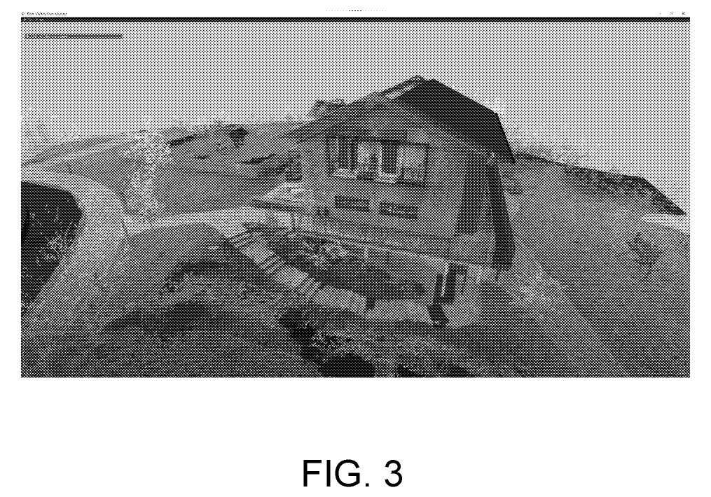

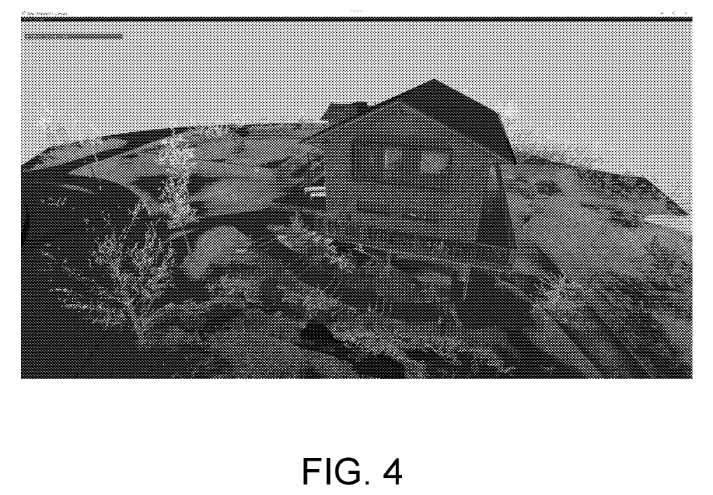

The alignment module 300 globally aligns the design data and the scan data respectively received and stored by the design data receiving module 100 and the scan data receiving module 200 as described above, such that the design data and the scan data are aligned with each other. In the present embodiment, an iterative closest point (ICP) algorithm is used to align the design data and the scan data with each other. Even when there are some differences between the design data and the scan data, many common features exist between the design data and the scan data, provided that both datasets pertain to a common structure. Accordingly, the scan data is aligned with respect to the design data by applying an ICP algorithm as a method of recognizing such common features. As the alignment module 300 aligns the scan data with respect to the design data in this manner, the geometry of the scan data is globally adjusted in a virtual space such that positions and orientations in the scan data are proximate to those in the design data. FIG. 3 illustrates an example of a state before design data and scan data are aligned with each other. FIG. 3 illustrates a state in which three-dimensional spaces defined by the design data and the scan data are superimposed on each other and displayed on a display device. It may be seen that the design data and the scan data are displayed as being globally offset from each other. When the alignment module 300 aligns the design data and the scan data with each other in this state, a state as illustrated in FIG. 4 is achieved. In FIG. 4, it may be seen that the design data and the scan data are aligned with each other and superimposed.

The assignment module 400 classifies and assigns points of the scan data aligned with the design data to correspond to respective constituent objects as described above. As described above, the design data includes information about three-dimensional shapes and positions of individual constituent objects constituting a target structure. In a state in which the scan data is aligned with respect to the design data, point clouds included in the scan data are recognized as corresponding to individual constituent objects spatially overlapping or proximate to the point clouds, and are thus classified as belonging to the respective constituent objects. At this time, the assignment module 400 classifies and assigns the point clouds of the scan data to correspond to the individual constituent objects based on spatial proximity. That is, the point cloud of data obtained by scanning a wall is classified and assigned as corresponding to a constituent object that represents the wall. Because the geometry of an actually fabricated or constructed structure may have errors compared to the design data, the assignment module 400 may assign each point as belonging to the nearest constituent object when a constituent object exists within a predetermined reference distance (e.g., 50 cm).

When the scan data received by the scan data receiving module 200 includes normal vectors of respective points, the assignment module 400 may also consider the orientation of these points to map the points to the constituent objects. As described above, the scan data stored by the scan data receiving module 200 may include, as a normal vector, a direction perpendicular to the surface of an object where each point is located. In this case, the assignment module 400 may perform assignment of a point cloud to a constituent object by considering both the surface orientation of the corresponding constituent object and the directions of the normal vectors of the points. For example, when a reference angular range is set to 30 degrees, the assignment module 400 classifies points as corresponding to a constituent object only when the points are proximate to the constituent object and the difference between the surface orientation of the proximate constituent object and the direction of normal vectors of the points is within 30 degrees.

The comparison module 500 performs an ICP algorithm on the constituent objects of the design data and a set of points corresponding thereto (hereinafter, referred to as a 'constituent point cloud') for which correspondence has been established, to generate, as error information, differences in position and orientation between the corresponding constituent object and the constituent point cloud. As described above, in a state in which the design data and the scan data are aligned by the alignment module 300, the differences in position and orientation may be calculated by comparing the corresponding constituent object with the constituent point cloud by using the ICP algorithm. The comparison module 500 generates and stores such differences in position and orientation as error information. In some cases, the comparison module 500 may additionally identify differences in geometry between the constituent object and the constituent point cloud as well as the differences in position and orientation, and store them as error information. For example, when a certain column at a construction site is only partially constructed, there may be differences between a constituent point cloud and a constituent object for the column, and thus, the comparison module 500 may identify such differences to obtain information about under-construction constituent objects.

In addition, the comparison module 500 may perform the ICP algorithm on constituent point clouds in various ways, depending on the data format of the constituent objects in the scan data. The comparison module 500 may apply a method of directly performing the ICP algorithm on a constituent object in the form of a mesh and a constituent point cloud corresponding thereto. In some cases, the comparison module 500 may sample an appropriate number of points from the surface of the constituent object and perform the ICP algorithm to compare the extracted points with the constituent point clouds. In this case, the comparison module 500 may perform the ICP algorithm by extracting points from the surface of the constituent object at a density similar to the density of the constituent point cloud, taking into account the density of the points (the number of points existing in a unit space) within the constituent point cloud corresponding to the constituent object.

The display module 600 displays the error information calculated by the comparison module 500 on a display device. The display device may display the error information on the display device in various manners. For example, only a constituent object where an error exists may be displayed on the display device. Alternatively, constituent objects with error information and constituent objects without error information may be displayed in different colors on the display device. In some cases, a three-dimensional shape formed by the constituent object or the constituent point cloud may be displayed in a virtual space on the display device such that the three-dimensional shape is distinguished by more emphasized colors according to a degree of error between the constituent object and the constituent point cloud.

Hereinafter, a process of performing a method of determining spatial differences between three-dimensional objects, according to the present disclosure, by using the apparatus configured as described above will be described with reference to FIG. 2.

First, the design data receiving module 100 receives and stores design data for a target structure (operation (a); S100). As described above, the design data is partitioned into units of constituent objects constituting the target structure, and includes information about the position, orientation, and geometry of three-dimensional shapes.

In addition, the scan data receiving module 200 receives scan data obtained by scanning the target structure and stores the scan data in the form of point cloud data (operation (b); S200). The scan data may be in the form of point cloud data from the beginning, or may be received in a form such as two-dimensional photographic images and camera intrinsic parameters and then converted into point cloud data through additional processing. In addition, as described above, the point cloud data may additionally include normal vectors of the respective points.

Once the design data and the scan data are received as described above, the alignment module 300 causes the scan data and the design data to be aligned and registered with each other (operation (c); S300). Even when there are some errors between the design data and the scan data, the design data and the scan data are overall three-dimensional geometric information about the same target structure (target space), the design data and the scan data are aligned to substantially coincide with each other. As described above, the alignment module 300 may align the design data and the scan data with each other by using an ICP algorithm. FIGS. 3 and 4 illustrate design data and scan data before and after alignment, respectively, as displayed on a display device.

In a state in which the design data and the scan data are aligned with each other as described above, the assignment module 400 classifies point clouds of the scan data into units of constituent point clouds to correspond to individual constituent objects of the design data (operation (d); S400). At this time, the assignment module 400 classifies the point cloud data to correspond to the nearest constituent object based on distances between individual points of the point cloud data and the constituent objects. Here, the assignment module 400 may classify the point cloud data by applying a criterion of whether the point cloud data is within a predetermined reference distance range as described above, or may classify the point cloud data by additionally considering a reference angular range. In places such as construction sites in progress, there may be tools, materials, debris, or the like that cannot be mapped to the constituent objects of the design data. Such objects may also be included in scan data obtained through methods such as photography, but because no corresponding constituent objects exist for the point cloud data of these objects, they may be excluded from processing by the assignment module 400. Operation (d) as described above may be performed by the assignment module 400 storing serial numbers of corresponding points for each constituent object, or conversely, storing a serial number of the corresponding constituent object for each point of the point cloud data.

Once operation (d) as described above is completed, the comparison module 500 performs an ICP algorithm on the corresponding constituent object and constituent point cloud to generate, as error information, differences in position and orientation between the constituent object and the constituent point cloud (operation (e); S500). Operation (e) as described above may be performed on all constituent objects, or may be performed on only some of the constituent objects of the design data. The execution of the ICP algorithm on the constituent object and the constituent point cloud may be performed on points sampled from the constituent object and the constituent point clouds. As described above, the ICP algorithm may be performed by sampling points from the constituent objects at a density similar to the density of the constituent point clouds.

The display module 600 displays a result of operation (e) on a display device (operation (f); S600). Various methods may be used for the display module 600 to display the differences between the constituent object and the constituent point cloud.

By the method described above, it is possible to easily determine whether an actually constructed structure has been built accurately according to design data. It is possible to quickly and accurately determine whether the position and orientation of structures such as columns, walls, or windows are accurate, and to easily identify the extent to which the position and orientation differ from the design. Furthermore, it is possible to readily detect instances of incomplete construction.

Although the present disclosure has been described above with preferred examples, the scope of the present disclosure is not limited to the embodiments described above.

For example, although the method of determining spatial differences between three-dimensional objects in the embodiment described above has been described as performing the operation of the display module 600 displaying error information on a display device, in some cases, it is also possible to implement the method of determining spatial differences between three-dimensional objects, without including this operation (f). In this case, the method of determining spatial differences between three-dimensional objects may be finalized simply by outputting the error information generated in operation (e) as a result value. The error information generated as described above may be delivered or transmitted to a separate device, to be utilized in various ways according to diverse purposes.

In addition, although the process of aligning the design data and the scan data with each other in operation (c) has been described as being performed by using the ICP algorithm, it is also possible to perform operation (c) by using other methods or algorithms.

What is claimed is:

1. A method of determining spatial differences between three-dimensional objects by comparing design data of a three-dimensional structure with scan data for the structure to identify a spatial difference between the design data and the scan data, the method comprising:
(a) receiving and storing, by a design data receiving module, the design data partitioned into constituent objects that constitute the structure;
(b) receiving the scan data obtained by scanning the structure and storing the same in the form of point cloud data, by a scan data receiving module;
(c) globally aligning, by an alignment module, the scan data with respect to the design data;
(d) classifying, by an assignment module, points of the scan data in the form of the point cloud data to correspond to the respective constituent objects of the design data, based on spatial proximity; and
(e) performing, by a comparison module, an iterative closest point (ICP) algorithm on at least some of the constituent objects of the design data and the points of the scan data classified as corresponding to the constituent objects, to generate differences in position and orientation between the constituent objects and the points of the scan data, which correspond to each other, as error information.

2. The method of claim 1, wherein the operation (c) comprises aligning the design data and the scan data with each other by performing an ICP algorithm between the design data and the scan data.

3. The method of claim 1, wherein the operation (d) comprises classifying each of the points of the scan data as a point corresponding to the constituent object only when a distance between the points of the scan data and the proximate constituent object of the design data is within a predetermined reference distance range.

4. The method of claim 1, wherein the scan data received in the operation (b) further includes information about normal vectors for at least some of the points of the point cloud data, and
the operation (d) comprises assigning each of the points of the scan data as a point corresponding to the constituent object only when a difference between an orientation of the proximate constituent object of the design data and a direction of the normal vector of the points of the point cloud data is within a predetermined reference angular range.

5. The method of claim 1, further comprising (f) displaying, by a display module, the error information calculated by the comparison module in the operation (e), on a display device.

6. The method of claim 1, wherein the operation (e) comprises calculating, by the comparison module, the error information by performing the ICP algorithm on points sampled from a surface of the constituent object of the design data and the points of the scan data classified as corresponding to the constituent object.

7. The method of claim 6, wherein the operation (e) further comprises sampling points from the surface of the constituent object at a density corresponding to a density of the points of the scan data, and performing the ICP algorithm, by the comparison module.

8. The method of claim 1, wherein the operation (e) comprises calculating, by the comparison module, as the error information, whether only a portion of the corresponding constituent object is present by performing the ICP algorithm on the constituent object and the points of the scan data corresponding thereto.

9. The method of claim 1, wherein the operation (b) comprises receiving, by the scan data receiving module, as the scan data, a set of a plurality of two-dimensional photographic images and intrinsic camera parameters of a camera that has captured the two-dimensional photographic images, and extracting the point cloud data therefrom.
